(19) United States
(12) Patent Application Publication
(10) Pub. No.: US 2009/0137066 A1
(43) Pub. Date: May 28, 2009

(54) Sensor for a magnetic memory device and method of manufacturing the same

(76) Inventors: Darren Imai, Los Gatos, CA (US); Cynthia A. Kuper, Villanova, PA (US)

Correspondence Address: MORGAN LEWIS & BOCKIUS LLP, 1111 PENNSYLVANIA AVENUE NW, WASHINGTON, DC, 20004, US

(21) Appl. No.: 12/289,952

(22) Filed: Nov. 7, 2008

Related U.S. Application Data
(60) Provisional application No. 60/996,610, filed on Nov. 27, 2007.

(51) Int. Cl. H01L 21/00

(52) U.S. Cl. 438/3; 257/E21.001

(57) ABSTRACT

The invention encompasses fabrication methods including the steps of preparing a silicon substrate, forming an amorphous III-V material layer on the silicon substrate, heating the amorphous III-V material layer, and epitaxially growing III-V material on the amorphous III-V material layer.

This application claims the benefit of pending U.S. provisional patent application No. 60/996,610, which was filed Nov. 27, 2007 and is incorporated herein by reference in its entirety.

### FIELD OF THE INVENTION

The present invention encompasses memory devices and more particularly memory devices using magnetic memory elements.

### BACKGROUND OF THE INVENTION

The rapid growth in the portable consumer product market (including the products for portable computing and communications) is driving the need for low power consumption non-volatile memory devices, with their inherent ability to retain stored information without power. The principal technology currently available in the marketplace for these applications is EEPROM (Electrically Erasable Programmable Read-Only Memory) technology, relying on charging (i.e., writing) or discharging (i.e., erasing) the floating-gate of a Metal-Oxide-Semiconductor (e.g., N-type) type transistor using so-called Fowler-Nordheim tunneling through the ultra-thin oxide layer of these structures. The charging of the gate creates results in an electron inversion channel in the device rendering it conductive (constituting a memory state 1). Discharging the floating gate (i.e., applying a negative bias) removes the electrons from the channel and returns the device to its initial non-conductive state (i.e., a memory state 0). One serious limitation to this technology is related to tunneling that limits the erase/write cycle endurance and can induce catastrophic breakdown (after a maximum of about 10⁶ cycles). Moreover, the required charging time—which is of the order of 1 ms—is relatively long.

In order to improve performance, so-called FeRAM (Ferroelectric Random Access Memory) technology has been developed. The FeRAM memory cell consists of a bi-stable capacitor and is comprised of a ferroelectric thin film that contains polarizable electric dipoles. These dipoles, analogous to the magnetic moments in a ferromagnetic material, respond to an applied electric field to create a net polarization in the direction of the applied field. A hysteresis loop for sweeping the applied field from positive to negative field defines the characteristics of the material. On removing the applied field, the ferroelectric material can retain a polarization known as the remnant polarization, serving as the basis for storing information in a non-volatile fashion. FeRAM would appear to be a promising technology with good future potential since relatively low voltages (typically about 5V) are required for switching as compared with about 12 to 15V for EEPROM. Moreover, FeRAM devices show 10⁸ to 10¹⁰ write cycle endurance compared with about 10⁶ for EEPROM, and the switching of the electrical polarization requires as little as about 100 ns compared with about 1 ms for charging an EEPROM. However, the need for an additional cycle to return a given bit to its original state for reading purposes (destructive read) aggravates the problems of dielectric fatigue. This, in turn, is characterized by degradation in the ability to polarize the material. In addition, owing to the behavior of these materials about their Curie temperature, as well as compositional stability (and associated changes in Curie temperature), even moderate thermal cycling promotes accelerated fatigue. Finally, fabrication process uniformity and control still remains a challenge.

Today, MRAM (Magnetoresistance Random Access Memory)—whose development began some 20 years ago—appears to hold the greatest promise for existing technologies in terms of read/write endurance cycle and speed. The technology relies on a writing process that uses the hysteresis loop of a ferromagnetic strip, while the reading process involves the anisotropic magnetoresistance effect. Basically, this effect (based on spin-orbit interaction) relates to the variation of the resistance of a magnetic conductor, dependent on an external applied magnetic field. The bit consists of a strip of two ferromagnetic films (e.g., NiFe) sandwiching a poor conductor (e.g., TaN), placed underneath an orthogonal conductive strip line (i.e., known as the word line). For writing, a current passes through the sandwich strip and when aided by a current in the orthogonal strip-line, the uppermost ferromagnetic layer of the sandwich strip is magnetized either clockwise, or counterclockwise. Reading is performed by measuring the magnetoresistance of the sandwich structure (i.e., by passing a current). Magnetoresistance ratios of only about 0.5% are typical, but have allowed the fabrication of a 16 Kb MRAM chip operating with write times of 100 ns (and read times of 250 ns). A 250 Kb chip was also later produced by Honeywell.

The discovery of so-called Giant Magnetoresistance (GMR) in 1989, implemented by sandwiching a copper layer with a magnetic thin film permitted further improvement in memory device performance. The GMR structures showed a magnetoresistance of about 6%, but the exchange between the magnetic layers limited how quickly the magnetization could change direction. Moreover magnetization curling from the edge of the strip imposed a limitation on the reduction in the cell size, or scaling.

Promising results were then obtained with the so called Pseudo-Spin Valve (PSV) cell made of a sandwich structure with two magnetic layers mismatched so that one layer tends to switch magnetization at a lower field than the other. The soft film is used to sense (by the magnetoresistance effect) the magnetization of the hard film—this latter film constitutes the storage media, having magnetization of either up or down (i.e., states 0 or 1). PSV structures are amenable to scaling but the reported fields required to switch the hard magnetic layer are still too high for high density integrated circuits. These devices appear to potentially represent a replacement for EEPROMs.

Further improvements in magnetoresistance (i.e., up to 40%) are obtained with spin-dependent tunneling devices (SDT). These devices are made of an insulating layer (i.e., the tunneling barrier) sandwiched between two magnetic layers. Device operation relies on the fact that the tunneling resistance, in the direction perpendicular to the stack, depends on the magnetization of the magnetic layers. The highest resistance is obtained when the magnetization of the layers is anti-parallel, and the parallel case provides the lowest resistance. The variation of spin (i.e., up or down) state density between the two magnetic layers explains this behavior. One of the layers is pinned while the second magnetic layer is free and used as the information storage media. SDT show promise for high performance non-volatile applications. Indeed there have been some reported values for write times as small as 14 ns with this approach. However, controlling the resistance uniformity (i.e., the tunneling barrier thickness and quality), and hence controlling the switching behavior from bit to bit remains a real challenge that has yet to be overcome in practical implementation.

Accordingly, there remains a need for a non-volatile memory device that is fast, reliable, relatively simple in design, inexpensive, and robust.

### SUMMARY OF THE INVENTION

The present invention encompasses a magnetic memory device that substantially obviates one or more of the problems due to limitations and disadvantages of the presently used magnetic memory devices.

One embodiment of the invention encompasses a sensor for a memory cell in a non-volatile magnetic memory device and method of manufacturing the same on a silicon substrate.

In one embodiment, the invention encompasses methods for making a magnetic memory cell including a Hall effect sensor on a substrate including the steps of:
(i) preparing a substrate;
(ii) forming an amorphous layer on the substrate on the substrate;
(iii) heating the amorphous layer; and
(iv) epitaxially growing a material on the amorphous layer

Another embodiment of the invention encompasses fabrication methods for making a magnetic memory cell comprising a Hall effect sensor on a substrate comprising the steps of:
(i) preparing a silicon substrate;
(ii) forming an amorphous III-V material layer on the silicon substrate;
(iii) heating the amorphous III-V material layer; and
(iv) epitaxially growing III-V material on the amorphous III-V material layer.

Another embodiment of the invention encompasses methods for making a magnetic memory cell comprising a Hall effect sensor on a substrate comprising
(i) preparing a silicon substrate;
(ii) forming a compliant buffer layer on the silicon substrate;
(iii) heating the compliant buffer layer; and
(iv) epitaxially growing a group III-V material on the compliant buffer layer.

Additional features and advantages of the invention will be set forth in the description that follows and, in part, will be apparent from the description or may be learned by practice of the invention. The objectives and other advantages of the invention will be realized and attained by the structure particularly pointed out in the written description and claims herein as well as the appended drawings.

It is to be understood that both the foregoing general description and the following detailed description are exemplary and explanatory and are intended to provide further explanation of the invention as claimed.

### BRIEF DESCRIPTION OF THE DRAWINGS

The accompanying drawings illustrate exemplary non-limiting embodiments of the invention and together with the description serve to explain the principles of the invention.

FIGS. 1A and 1B show schematic plan and top views of an exemplary sensor in accordance with the present invention;

FIGS. 2A-2H show various exemplary stages of fabrication for an exemplary sensor in accordance with the present invention.

FIGS. 3A-3D show various exemplary stages of fabrication for insulating an exemplary sensor in accordance with the present invention.

FIG. 4 shows an exemplary embodiment of an electroplating system in accordance with the present invention.

FIG. 5 shows a schematic view of an exemplary embodiment of a memory cell in accordance with the present invention.

FIGS. 6A-6D show various exemplary stages of a fabrication process for an exemplary coil using a subtractive process in accordance with the present invention.

FIG. 6E shows top down view of a fabricated exemplary coil in accordance with a fabrication process of the present invention.

FIGS. 7A-7F show various exemplary stages of fabrication for an exemplary coil using a damascene process in accordance with the present invention.

FIGS. 8A and 8B show schematic plan and top views of another exemplary embodiment of a memory cell in accordance with the present invention.

FIG. 9 shows a cross-section and top down schematic of the preferred embodiment.

FIGS. 10A and 10B show a partial side view of an exemplary magnetic switch in accordance with the present invention.

### DETAILED DESCRIPTION OF THE INVENTION

### General Description

The invention encompasses methods for making a magnetic memory cell including a Hall effect sensor on a substrate including the steps of:
(i) preparing a substrate;
(ii) forming an amorphous layer on the substrate on the substrate;
(iii) heating the amorphous layer; and
(iv) epitaxially growing a material on the amorphous layer.

In one embodiment, the substrate is a silicon substrate.

In another embodiment, the amorphous layer is comprised of a group III-V material.

In another embodiment, the III-V material is a low temperature III-V material.

In another embodiment, the amorphous III-V material layer is GaAs.

In another embodiment, the epitaxially grown material is a 2DEG structure.

In another embodiment, the epitaxially grown material is a 2DEG structure constructed from AGaAs/GaAs.

In another embodiment, the method further includes using high electron mobility materials to form a Hall effect sensor on a silicon substrate, which will be used to detect the direction of magnetization of a magnetic storage element or bit.

Another embodiment of the invention encompasses fabrication methods for making a magnetic memory cell comprising a Hall effect sensor on a substrate comprising the steps of:
(i) preparing a silicon substrate;
(ii) forming an amorphous III-V material layer on the silicon substrate;
(iii) heating the amorphous III-V material layer; and
(iv) epitaxially growing III-V material on the amorphous III-V material layer.

In another embodiment, the III-V material is a low temperature III-V material.

In another embodiment, the III-V material layer is GaAs.

In another embodiment, the epitaxially grown material is a 2DEG structure.

In another embodiment, the epitaxially grown material is a 2DEG structure constructed from AGaAs/GaAs.

In another embodiment, the method further comprises the steps of:
(i) preparing a silicon substrate;
(ii) forming a silicon dioxide layer, and
(iii) epitaxially growing a SiGe layer on the silicon dioxide layer.

In another embodiment, the SiGe layer is the basis for a Hall effect sensor.

In another embodiment, the magnetic storage element is comprised of plated magnetic material, which can have its magnetization switched by applying a current to a coil proximate to the magnetic material.

In another embodiment, the magnetic material is a soft magnetic material.

In another embodiment, the soft magnetic material is 80:20 NiFe, 45:55 NiFe, or NiFeCo.

In another embodiment, the magnetic material is deposited onto the substrate to form a horseshoe-shaped magnet.

In another embodiment, the magnetic storage element is comprised of a sputter deposited or evaporated magnetic material, which can have its magnetization switched by applying a current to a coil proximate to the magnetic material.

In another embodiment, the magnetic material is a soft magnetic material.

In another embodiment, the soft magnetic material is 80:20 NiFe, 45:55 NiFe, or NiFeCo.

In another embodiment, the starting substrate is an SOI-type substrate with the device side of the SOI comprised of a high electron mobility material.

In another embodiment, the starting substrate is comprised of a SiGe SOI substrate.

Another embodiment of the invention encompasses methods for making a magnetic memory cell comprising a Hall effect sensor on a substrate comprising
(i) preparing a silicon substrate;
(ii) forming an compliant buffer layer on the silicon substrate;
(iii) heating the compliant buffer layer; and
(iv) epitaxially growing a group III-V material on the compliant buffer layer.

In another embodiment, the group III-V material is GaAs.

In another embodiment, the epitaxially grown material is a 2DEG structure.

In another embodiment, the epitaxially grown material is a 2DEG structure constructed from AGaAs/GaAs.

### DESCRIPTION OF ILLUSTRATIVE EMBODIMENTS OF THE INVENTION

Reference will now be made to non-limiting illustrative embodiments of the present invention, examples of which are illustrated in the accompanying drawings.

The invention encompasses a magnetic memory device and a method for making the same.

The fabrication process of an exemplary embodiment of a memory cell of the invention may be divided into 2 parts: (1) fabrication of a sensor and (2) fabrication of a magnetic switch.

In certain illustrative embodiments, the Hall effect sensor is generally fabricated with high mobility materials, such as group IV or, for example, a group III-V materials (i.e., compounds formed from groups IV or groups III and V elements of the periodic table). Examples of IV or III-V materials include, but are not limited to, SiGe, GaAs, InAs, InSb, and related two-dimensional electron gas (2DEG) structures.

A 2DEG structure based on a GaAs/AlGaAs hetero-structure may be formed at the hetero junction interface of a modulation-doped hetero-structure between a doped wide band-gap AlGaAs material (i.e., barrier) and an un-doped narrow band-gap GaAs material (i.e., well). Ionized carriers (from the dopant) transfer into the well, forming the 2DEG. These carriers are spatially separated from their ionized parent impurities and, therefore, allow for high carrier mobility and a large Hall effect. In certain embodiments, other high electron mobility materials, such as, for example, graphene, which exhibit a Hall effect or a quantum Hall effect, may also be used in this device.

A majority of currently available memory devices are based on a complementary metal-oxide semiconductor (CMOS) structure, which are built on a silicon substrate that is cheaper and easier to process, than the typical III-V substrate. However, silicon does not provide the high carrier mobility that is desirable for a large Hall effect. The inventors found that the compositions described herein surprisingly create high mobility structures, such as GaAs based structures, on a silicon based platform that overcome the cost and processing limitations of known devices.

Forming high carrier mobility structures on silicon (Si) poses a challenge because the crystalline lattice of these structures, for example GaAs, are different than that of Si.

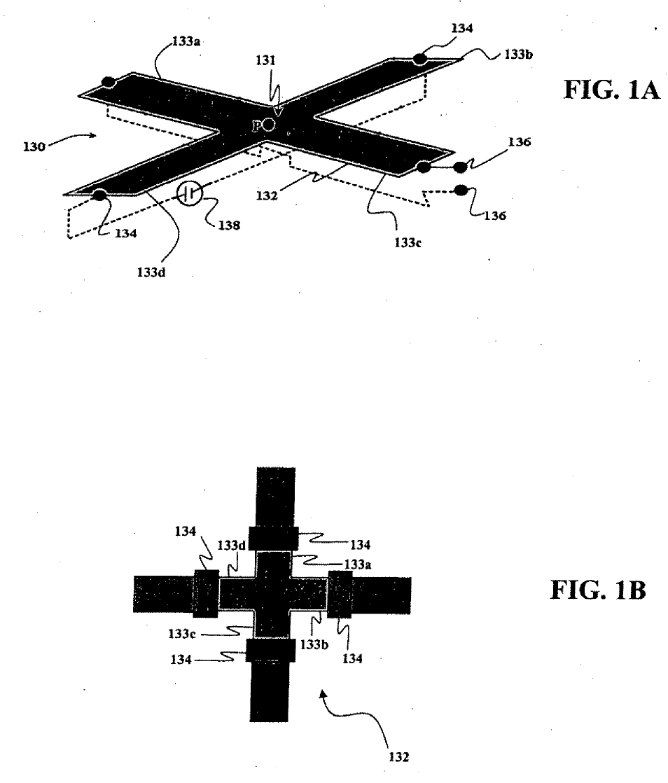

FIGS. 1A and 1B illustrate a sensor 130 according to the present invention. In particular, the sensor 130 includes a Hall effect sensor 132 and output terminals 136 connected to a voltage detector (not shown) to detect the stored data in a magnetic switch, the description of which is provided below. The Hall effect sensor 132 includes a geometrically defined semiconductor structure with current-carrying arms 133a-133d. Input terminals 134 are connected to a power supply 138 and the output terminals 136 are positioned perpendicularly to the direction of current flow. Although the Hall effect sensor 132 is shown as having a “Greek cross” shape for purposes of illustration, any suitable shape (e.g., rectangle) may be used without departing from the scope of the present invention.

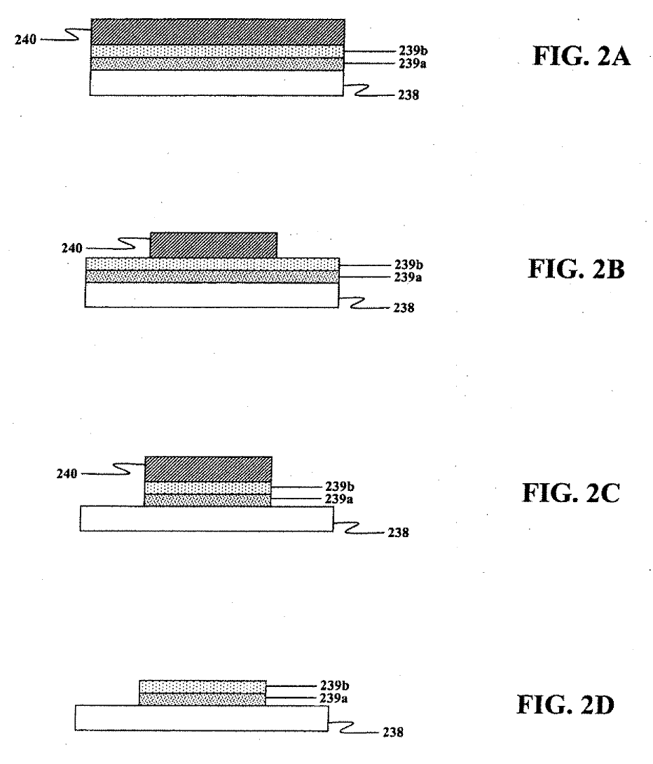

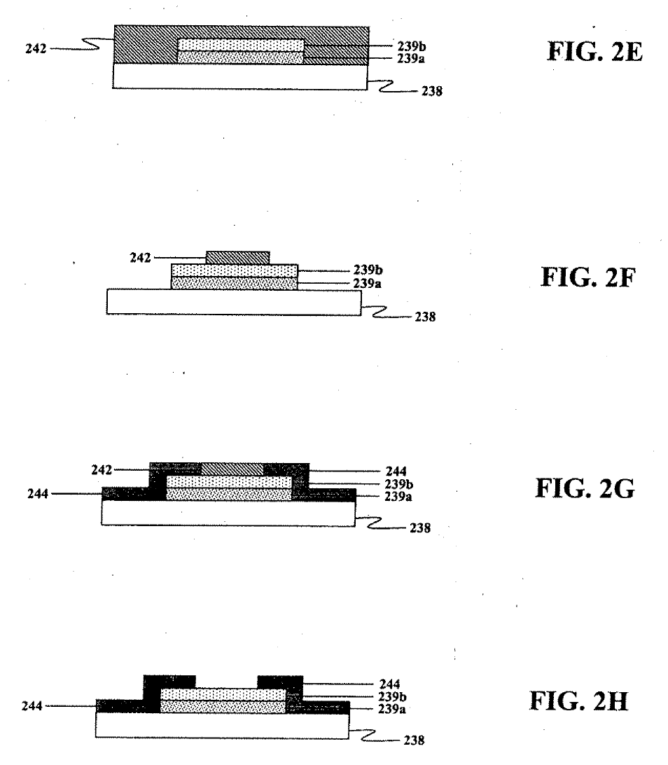

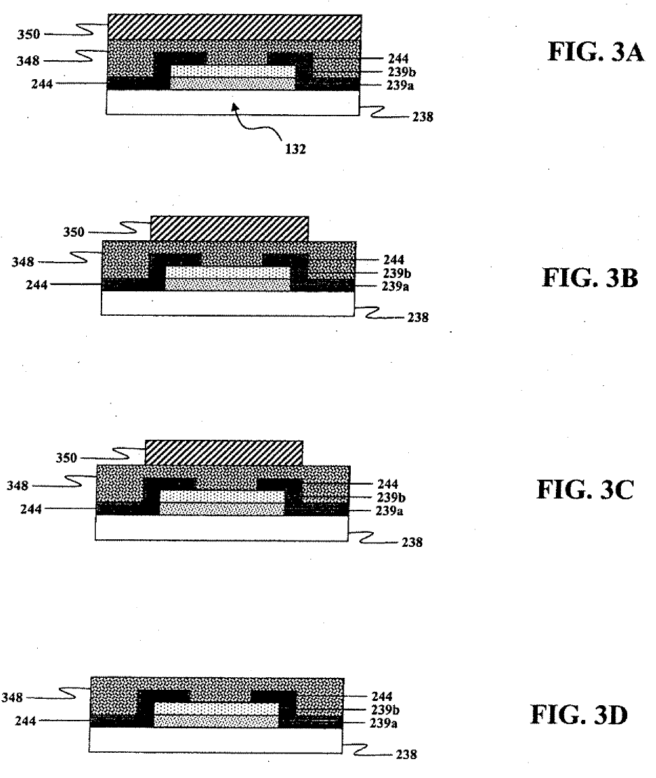

The fabrication process for the sensor 130 will now be explained with reference to FIGS. 2A-2H and 3A-3D. The Hall effect sensor 132 is fabricated with high mobility materials, such as group IV or III-V materials (i.e., compounds formed from groups IV or III and V elements of the periodic table), or any other high electron mobility material that shows a Hall or quantum Hall effect, materials such as, for example, graphene. Examples of IV or III-V materials include, but are not limited to SiGe, GaAs, InAs, InSb, and related two-dimensional electron gas (2DEG) structures. A 2DEG structure based on a GaAs/AlGaAs hetero-structure may be formed at the hetero junction interface of a modulation-doped hetero-structure between a doped wide band-gap AlGaAs material (i.e., barrier) and an undoped narrow band-gap GaAs material (i.e., well). Ionized carriers (from the dopant) transfer into the well, forming the 2DEG. These carriers are spatially separated from their ionized parent impurities and, therefore, allow for high carrier mobility and a large Hall effect. An example of a group IV material is SiGe, which with its higher electron mobility with respect to standard silicon, may also work as a sensor material.

FIGS. 2A-2D illustrate the various fabrication stages of the Hall effect sensor 132 in accordance with an exemplary embodiment of the present invention. A suitable wafer, such as a silicon wafer 238 is prepared. As discussed above, silicon is not a compatible crystal substrate onto which crystalline GaAs or other crystalline III-V materials can be deposited or grown because silicon and crystalline III-V materials do not have the same lattice structure. In accordance with the present invention, a layer of low temperature amorphous GaAs 239a or other amorphous III-V film is deposited onto the silicon wafer 238. Silicon Dioxide and/or layers of other compliant buffer layers may be used between the Silicon base wafer 238 and the amorphous GaAs layer 239a, or may replace the amorphous GaAs layer and become layer 239a, in order to reduce the lattice strain due to the lattice mismatch between the materials. Techniques for making this type of structure are well documented in the literature, but usually as a way of making III-V active devices on silicon with varying success. In the preferred embodiment of this invention, the high mobility layer is fabricated to form a Hall effect sensor to sense the direction of magnetization of a magnetic storage bit for a magnetic memory device. After depositing the amorphous GaAs or other amorphous III-V film or compliant buffer layer, the silicon wafer 238 is heated at a temperature of about 580° C. or greater. In turn, the amorphous GaAs layer 239a or other amorphous III-V film or compliant buffer layer undergoes an annealing process (i.e., the amorphous GaAs layer 239a fuses with the silicon wafer 238). The temperature applied will take into account not only the effective annealing temperature for the amorphous GaAs or like film, but also previous temperature sensitive operations, such as inplants and/or diffusion, and the subsequent operations that may require higher temperatures, such as furnace operations (CVD, Epitaxial film deposition, etc.) Next, a crystalline GaAs layer 239b or other high mobility layer, such as a 2DEG film, is grown onto the silicon wafer 238 through epitaxy (for example MBE or furnace growth), on the amorphous GaAs layer or like film 239a which provides a compatible crystalline lattice onto which crystalline GaAs or other high mobility film can be grown. Here, the amorphous GaAs layer or like film 239a serves as an interface between the silicon wafer 238 (or additional buffer layer) and the crystalline or epitaxial GaAs or like high mobility layer 239b. Moreover, the amorphous GaAs or like film layer 239a also serves as a buffer zone or semi-insulating layer between the silicon wafer 238 and epitaxial GaAs layer or other high mobility film 239b. In an exemplary embodiment, the crystalline GaAs layer 239b may be an n-type active GaAs layer grown to about 0.5-0.6 μm.

Following the growth of the epitaxial layer 239b of GaAs, a layer of photoresist 240 (e.g., any high contrast photoresist commonly used in the production of semiconductor circuits) is spun onto the wafer 238 (FIG. 2A). The resist is processed as recommended by the resist manufacturer with subsequent process optimization in the wafer fabrication area to obtain the desired resist geometry. The wafer is then aligned and patterned using the appropriate wavelength of light and exposure dose for the resist used, on an exposure tool (e.g. stepper, step and scan (aka. Scanner) or other commercially available systems) (FIG. 2B). A mesa etch process is then carried out for isolating the sensor 132. The etch process can involve wet etching with, for example, a standard H₂O₂/H₃PO₄/H₂O solution or a dry process, such as RIE, ion beam etching or implant isolation. (FIG. 2C).

Following the isolation process, the input terminals 134 and output terminals 136 (FIG. 1A) are deposited with an ohmic contact layer through a lift-off process or other typical metallization process (e.g. deposit, pattern, then etch (wet or dry) process). As shown in FIGS. 2E-2H, the lift-off process can involve spinning a double resist layer 242 of two different types of films such as, for example, LOL1000/AZ1811 or BARLI/AZ1811. Lift-off structures are well known to those knowledgeable in the art, and several different variations of the lift-off structure can be found in the literature. The lift-off profile (i.e., under-etching) is provided by the difference of sensitivity between the underlayer and the top resist patterning layer during the development process, or by a difference in etch rate (usually in an oxygen containing plasma) of the top layer vs. the bottom layer as in the case of the BARLI/AZ1811 stack. Lift-off layers using a single resist film, such as the AZ® nLOF™ 2000 series resist, can also be utilized for this process. As used herein, the term “AZnLOF,” “AZ® nLOF™,” and “AZ nLof” are used synonymously and refer to AZ Electronics Materials' 2000 series i-line photoresists formulated for use in lift-off lithography processes. In various illustrative, non-limiting embodiments, the nLOF 2000 series photoresists work in both surfactant and non-surfactant containing tetramethylammonium hydroxide (TMAH) developers using standard conditions. In various illustrative, non-limiting embodiments, the nLOF 2000 series photoresists can be used for coating thicknesses beyond 7.0 μm and achieving aspect ratios of up to 4:1. A contact layer 244 of suitable material, such as Mo or NiPd or any other conductive film that can form a good reliable ohmic contact, but is compatible with an advanced CMOS process, is evaporated, PVD'd or sputtered onto the wafer 238 to a thickness of about 400 nm or greater to form ohmic contacts 134, 136 to be used as input and output terminals of sensor 130.

Following the deposition step, the lift-off process is completed by placing the wafer 238 in a suitable resist stripper in order to remove any unnecessary portions of the metal layer 244 deposited onto the lift-off resist layer. Ultrasonic or megasonic tanks may be used to enhance the removal of the resist film. The mask design can also incorporate additional features which will enhance the lift-off process by breaking up large areas into smaller easier to undercut areas. After appropriate cleaning, the contacts (i.e., Mo or NiPd layer 244) undergo rapid thermal annealing (RTA). The annealing is carried out at about 340° C. or greater for about 40 seconds or greater in an RTA chamber filled with nitrogen (N₂).

Once the Hall effect sensor 132 is fabricated, an insulating layer 348 is deposited onto the Hall effect sensor 132. The insulating layer 348 is made of a suitable material, such as a PECVD or LPCVD nitride or oxide.

For illustrative purposes only, FIGS. 3A-3D show an insulating layer 348 of dielectric film of PECVD nitride deposited onto the Hall effect sensor 132. Once the insulating layer 348 is deposited, a positive resist layer 350 (e.g., AZ1811, AZ5206, or any other i-line, 248 nm or 193 nm resist) is spun onto the insulating layer 348. For purposes of explanation, AZ1811 is used. The resist layer 350 is then softbaked in an oven or on a hot plate in accordance with the manufacturer recommended process conditions and optimized for the particular wafer fabrication process.

Then, the wafer 238 is placed into an appropriate exposure tool for alignment and exposure. The resist layer 350 is patterned in such a way as to make openings (i.e. vias) over the Hall effect sensor's ohmic contacts and alignment marks (if any).

After exposure, the resist layer 350 is developed in a suitable solution (in the case of 248 nm or 193 nm resists, a post-exposure bake is necessary for chemical amplification to occur), such as a dilute TMAH for a suitable amount of time (e.g., develop time is dependent on the thickness of the resist and the normality of the developer solution). The wafer 238 is then rinsed in de-ionized water and dried. Once the wafer 238 is done with the patterning step, it is etched using RIE to open vias down to the ohmic contacts. The preceding photolithography and etching operations for opening of the vias can be postponed until the metallization steps of the accompanying CMOS fabrication. Thus, the nitride layer in this illustration will serve to protect the ohmic contact layer from harm during the CMOS fabrication.

The CMOS fabrication step can now proceed to build up the needed active and passive elements to complete the memory cell using well known semiconductor processes and recipes. If the memory is to be used as embedded memory, the rest of the active device can also be fabricated at this time in conjunction with the active and passive elements needed for driving, and reading the memory cell.

Once the sensor 130 is fabricated and all of the CMOS processing is completed up to the metallization steps, a magnetic switch according to the present invention is fabricated over the insulating layer 348. An exemplary magnetic switch according to the present invention includes a magnetic component or material to hold data and a write line or coil structure to switch the magnetization of the magnetic component. The write line or coil (connected to a current source, not shown) is made of a conductive material, such as the metal TiN/Ti/Cu/ECD Cu. However, any other suitable conductive material (e.g., TaN/Ta/Cu/ECD Cu or Aluminum) may be used without departing from the scope of the present invention.

The magnetic component may be a permanent magnet or a ferromagnetic material (e.g., nickel or nickel-iron magnet). Traditional methods for fabricating magnetic materials (e.g., Alnico and Martensitic steel) involve synthesis routes that include, for example, melting different components, casting, and high temperature (typically, above 800° C.) thermal processing (e.g., quenching). Other synthesis routes include sintering and extrusion. These methods are incompatible with micro-technology or wafer-scale processing due to the extremely small sizes of the components.

Electroplating, on the other hand, allows for relatively good definition of element shapes with fewer defects on element walls. It is also an inexpensive and relatively simple process to implement. Three-electrode systems can be used to monitor the stoichiometry of deposited alloys.

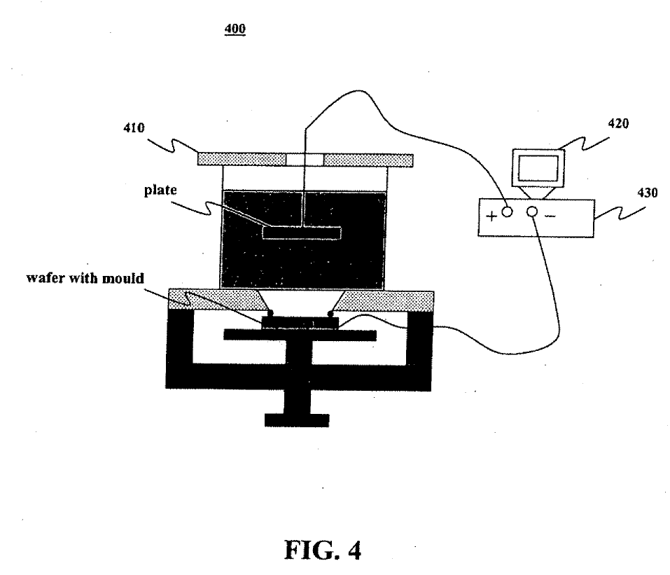

Electroplating will be used in explaining the fabrication process of the magnetic switch; however, any suitable synthesis route may be utilized, such as PVD, sputter deposition or evaporation. As shown in FIG. 4, an electroplating system 400 includes an electroplating cell 410, a computer 420, and a computer-driven potentiostat/galvanostat 430. The computer 420 is connected to electroplating cell 410 through the potentiostat/galvanostat 430 to control the electroplating process. The potentiostat/galvanostat 430 can function as either a potentiostat or a galvanostat. An external magnetic field can be utilized to orient the magnetic film for easier switching (e.g. the alignment of the easy and hard axis magnetization).

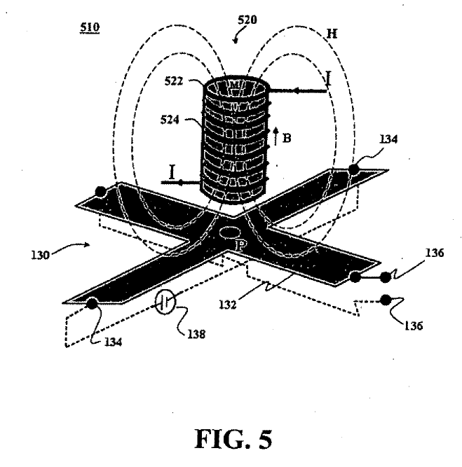

FIG. 5 illustrates an exemplary embodiment of a magnetic switch 520 of a memory cell 510 according to the present invention. In particular, the magnetic switch 520 includes a magnetic component 522 to hold data and a coaxial coil 524 to write the data in to the magnetic component 522. The coaxial coil 524 is disposed about the magnetic component 522. Although magnetic component 522 is shown as having a generally cylindrical shape for purposes of illustration, any suitable shape (e.g., square, rectangle, horseshoe) may be used without departing from the scope of the present invention. Furthermore, the coaxial coil 524 is shown for purposes of illustration as having six (6) turns around magnetic component 522. However, any suitable number of turns may be used without departing from the scope of the present invention.

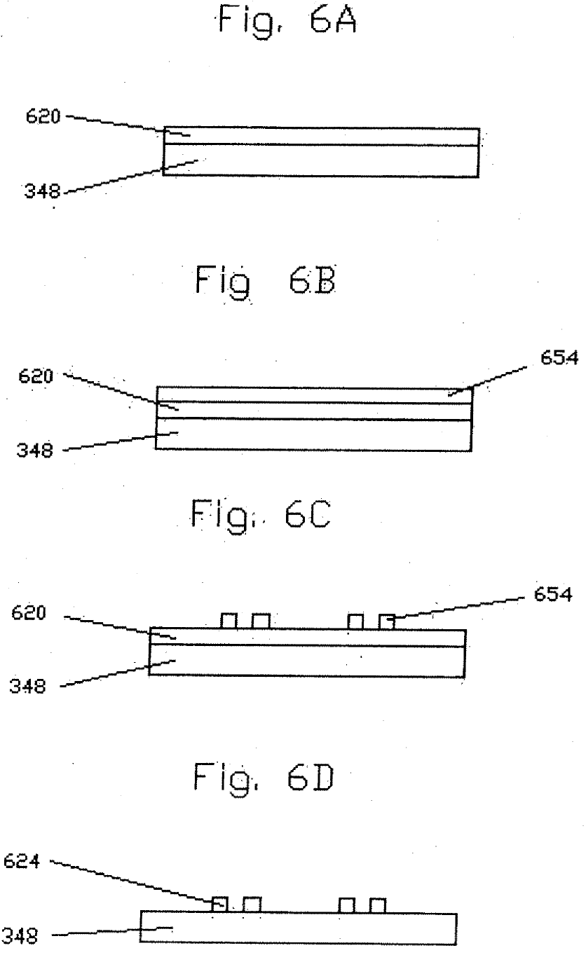

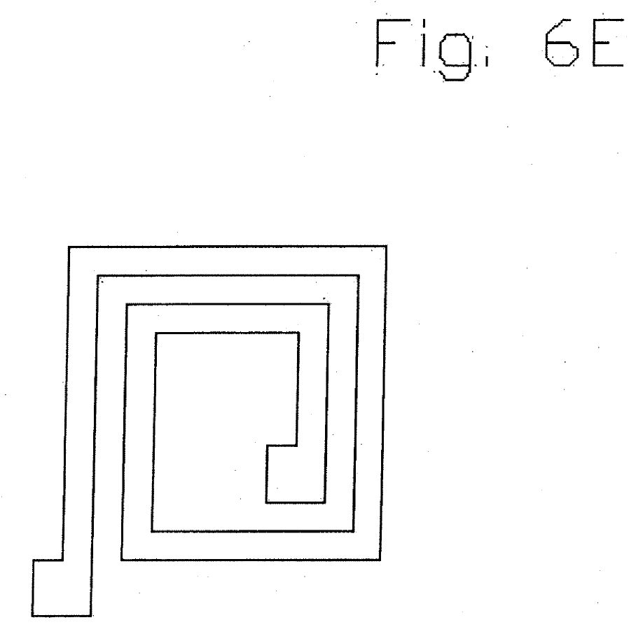

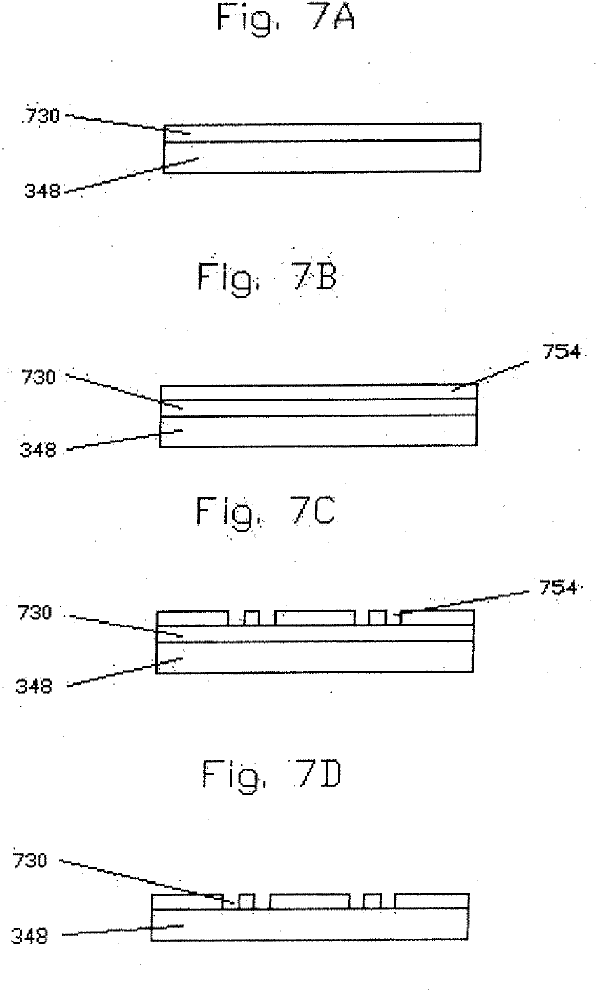

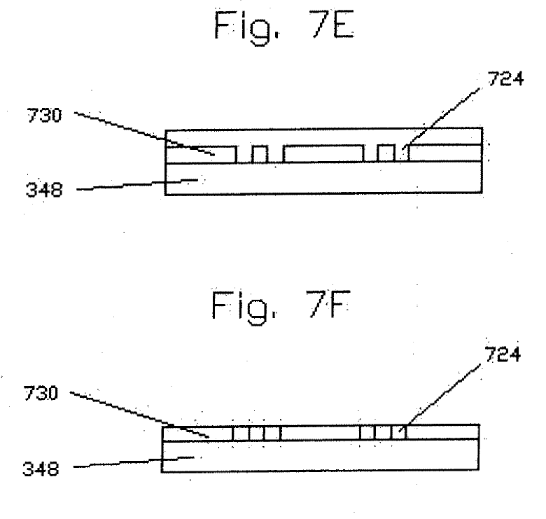

The fabrication process for the magnetic switch 520 will now be discussed with reference to FIGS. 6A-6E, and 7A-7F. The general approach to fabricating the magnetic switch 520 is to first fabricate the coil 524 and then fabricate the magnetic component 522.

FIGS. 6A-6D illustrate various stages of a first exemplary fabrication process of a coil 624. The coil 624 can be formed in a variety of different shapes, such as a linear coil wrapped around a magnetic yoke element, but for this illustration of the preferred embodiment of the invention, a planar or “pancake” coil is chosen. The coil 624 can be defined with well known semiconductor fabrication processes for aluminum traces or with a damascene copper metal layer.

In the case of aluminum, an aluminum conductive layer 620 is deposited onto the substrate 238. Tungsten interconnects can be used to connect down to the ohmic sensor pads 134 (not shown). Using well known photolithography techniques a pattern for the coil and the metal traces for the sensor force lines and read lines are defined 654. Next a RIE process to define the coil 624 and remove any unwanted metal is used (typically a Chlorine based chemistry is used for this operation). The resist is then removed using standard processing techniques by either dry etching the resist or by a combination of dry and wet stripping of the resist. An inter-layer dielectric is then deposited over the structure using LPCVD or PECVD. This dielectric layer can be silicon dioxide, TEOS or a low k dielectric. The layer is then planarized using well known CMP processes.

Another embodiment of the structure utilizes copper dual damascene processes to form the coil and metal traces. For dual damascene copper traces a dielectric layer 730, typically silicon dioxide, is deposited over the substrate 348. Other dielectric and dielectric stacks can also be used (e.g. low k dielectrics such as carbon containing films) without departing from the scope of the present invention. A via pattern (not shown) for connection down to the sensor ohmic pads 134 are defined and transferred into the dielectric layer using well known lithographic and etching techniques. Once the resist is removed from the via layer, the patterning of a trench (FIGS. 7B and 7C, using a photoresist layer 754) in the shape of the coil and metal traces is defined and transferred into the dielectric layer (FIG. 7D). The transfer of the pattern into the dielectric film is done by RIE. A plating seed layer of TaN/Ta/Cu is deposited onto the substrate 348 using PVD. Alternatively, a TiN/Ti/Cu layer can also be used as the plating seed layer. Next, electroplated copper is deposited onto the wafer using well established processes (FIG. 7E). The wafer is planarized using CMP to remove the excess copper down to the dielectric layer (FIG. 7F). CMP down to the dielectric layer not only removes excess copper, but electrically isolates the various metal traces from each other. A silicon nitride dielectric layer is deposited over the wafer to cap the exposed copper to avoid copper diffusion and act as a stop layer for further processing.

For the purpose of illustration, a single coil layer has been described above, but it is obvious to those knowledgeable in the art, that multiple coil layers can be made using the above processes. Also, that the metallization layers can be incorporated into the normal metallization scheme of a CMOS device, taking advantage of the multilevel metal to route the necessary write and read lines of the device. In fact, after the definition of the Hall effect sensor and ohmic contacts, a typical CMOS process can be utilized to build the necessary transistors and other active and passive structures needed to drive and sense the memory cell.

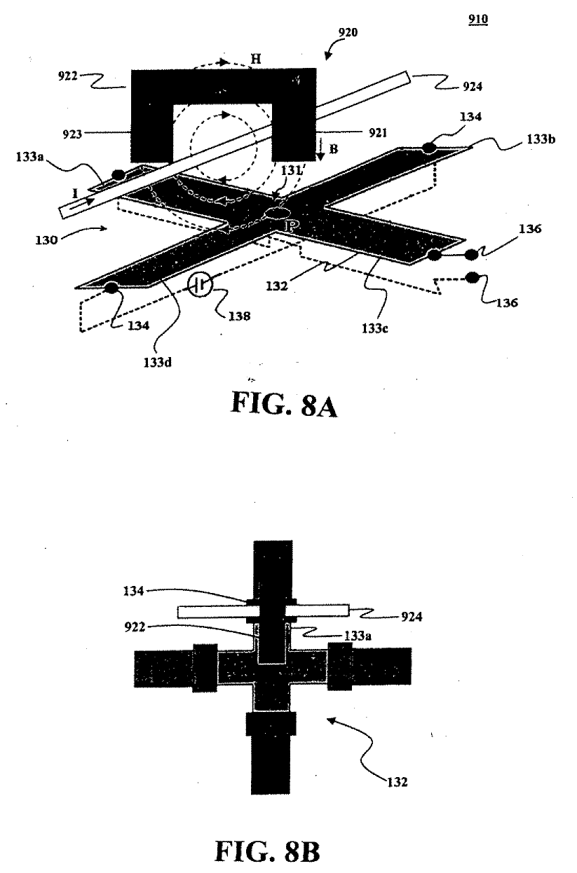

To form the magnetic element 520, first a via must be formed over the sensor element to reduce the spacing loss of the magnetic field produced by the magnetic element 520. In the case of a “horse shoe” shaped magnetic element (FIG. 8A), an additional via will be formed for the “return” of the magnetic element 920. The horse shoe shaped magnetic element shown in FIGS. 8A and 8B show an exemplary example of a more efficient magnetic element which enhances the magnetic coupling to the coil structure and reduces stray magnetic fields by providing a closer “return” leg for the magnetic flux. Using photolithography to define the via pattern 952, the pattern is transferred through the interlayer dielectric using RIE, stopping on the silicon nitride layer above the sensor. At the same time, via openings 954 to connect down to the Hall Sensor 132 Ohmic contacts 134, can be made. To further decrease the spacing loss the nitride layer over the Hall sensor cross intersection, may also be removed, but care must be taken to protect the sensor material below from over-etching and degradation from being exposed.

In one form of the preferred embodiment an electroplated magnetic element 920 is formed by depositing a conductive film onto the substrate 348 for use as the plating seed layer, such as a 80:20 NiFe alloy. The use of non-magnetic conductive films can also be used, but the thickness of which will be added to the spacing between the sensor and the magnetic element. Using photolithography a pattern for the magnetic element 920 is formed. The magnetic material (for the purpose of illustration a nominal alloy of 80% Ni and 20% Fe is used, but any magnetic material with high remanent magnetization can be used, such as 45:55 NiFe or NiFeCo) is then plated onto the wafer through the pattern formed by the photoresist. The plating of magnetic films such as the 80:20 NiFe film presented here, is known to those knowledgeable in the art. An external magnetic field can be used to orient the magnetic material (i.e. to set the easy and hard axis magnetization) for easier switching of the direction of magnetization. The resist pattern is stripped using a standard resist stripping process, and the conductive plating seed layer is removed using a dry process such as sputtering etching or RIE with a high Argon content or by ion milling. The magnetic bit structure is then covered with a dielectric coating and contacts to the write and read lines are created during the normal CMOS metallization steps.

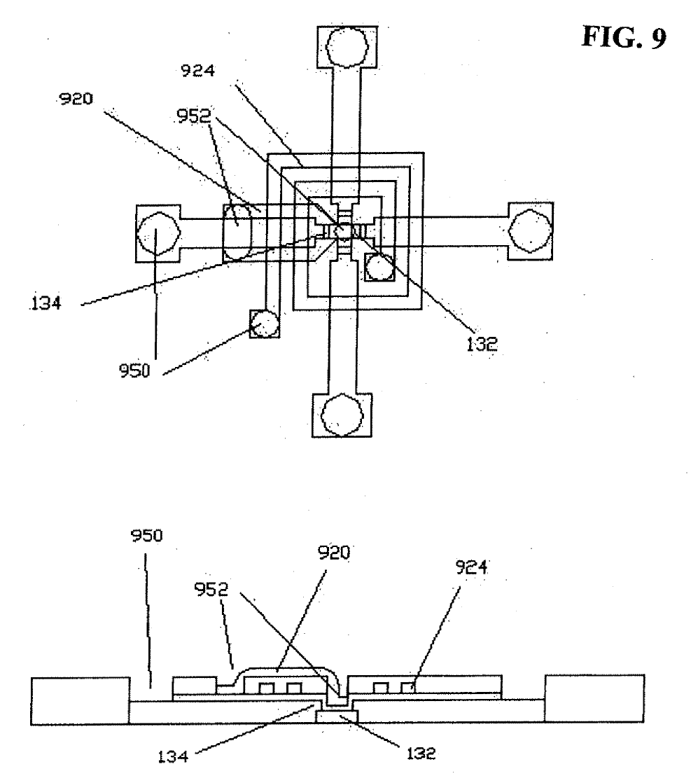

Another form of the preferred embodiment utilizes lift-off of a sputtered or evaporated magnetic film. With the vias down to the sensor and for the return of the magnetic element 920 formed into the interlayer dielectric, photolithography is used to make a lift-off resist mask. Lift-off resist masking can be done in both single layer (e.g. AZ® nLOF™ 2000 series resist) or double layer (e.g. LOL1000/positive photoresist) resist schemes. For the purposes of this discussion a single layer lift-off process is illustrated, but alternative lift-off techniques can be used without departing from the scope of the current invention. AZ® nLOF™ 2000 series photoresist is spun onto the substrate 348. The viscosity of the resist is chosen based on the final thickness of the lift-off structure needed, in this case, in the range of 1 to 5 microns. The resist is processed as directed by the manufacturer to form a lift-off profile. Large lift-off areas may be subdivided into smaller areas to aid in the lift-off of material after deposition. The magnetic material, in this case 80:20 NiFe, but any magnetic material or alloy can be used, is deposited onto the substrate 348 using PVD, sputtering or evaporation techniques, to the desired thickness. The wafer is then put into a lift-off bath, generally a strong resist stripper with ultrasonic or megasonic transducer to aid in the lift-off process. Once the unwanted magnetic material and lift-off resist are removed, the magnetic element is complete. A cross-section and top down schematic representation of the preferred embodiment using either the plated or sputtered/evaporated magnetic element 920 can be seen in FIG. 9.

In a second embodiment of the current invention, the high electron mobility layer for the sensor is created by manufacturing a SOI (silicon on insulator) type composite wafer. Here, for the case of illustration, but any type IV or III-V material that can be processed in this way can be used, SiGe is provided as the high electron mobility material. SiGe SOI wafers can be commercially purchased from select wafer suppliers. The process to make SOI wafers is well known, but generally, two substrates, one Silicon wafer and one, in this case, SiGe wafer are used. At least one of the substrates has a silicon dioxide layer deposited or grown onto the surface. The wafers are then placed together to form a weak bond (Van der Waal forces) to hold the wafers together, and then the wafers are placed in a fusion furnace to form a strong fusion bond (typically in temperatures of 1000 deg C. or greater). The SiGe wafer side is then processed down to the desired thickness. Once the high electron mobility layer is completed, the process for defining the Hall effect sensor is the same as illustrated above and continues to follow the processing as outlined.

The operation of an exemplary embodiment of a memory cell of a magnetic memory device according to the present invention will now be discussed. In general, the Hall effect sensor 132 responds to a physical quantity to be sensed (i.e., magnetic induction) through an input interface and, in turn, outputs the sensed signal to an output interface that converts the electrical signal from the Hall effect sensor into a designated indicator. For example, when the Hall effect sensor 132 is subjected to a magnetic field (H) from the magnetic component (e.g., magnetic component 522 from FIG. 5 or magnetic component 922 from FIG. 8), a potential difference appears across the output terminals 136 in proportion to the field strength. When the Hall effect sensor 132 is subjected to an equal and opposite magnetic field, an equal and opposite potential difference appears across the same output terminals 136. The Hall effect sensor 132 thus acts as a sensor of both the magnitude and direction of an externally applied magnetic field.

In general, the shape and material used for the magnetic switch determines the strength of magnetization (M) responsible for generating a magnetic field (H) around sensor 130. The current (I) applied to the wire (e.g., coil 524 from FIG. 5 or write line 924 from FIG. 9) determines the strength of the induced magnetization (H) generated around the magnetic component to set the direction and intensity of the magnetization (M). If the write line is a coil, the number of turns of the coil around the magnetic component also determines the strength of the induced magnetization (H). The direction of the magnetization (M) of the magnetic component determines the value of the magnetic stored data (i.e., “0” or “1”) in the magnetic switch. The Hall effect sensor 132 is characterized by a voltage signal V_{Hall} that is generated in response to the magnetic field (H) emanating from the magnetic switch detected at point P.

A current (I) (e.g., current pulse) is sent through the coil or write line in such a way as to generate a magnetic field H_{wire}. The magnitude of the current is chosen to be sufficient to change (i.e., flip) the magnetization of the magnetic component. The magnetic field generated by the magnetic component needs to be sufficient for the sensor 130 to detect it at detection point P. After detection, the sensor 130 needs to generate a response (V_{Hall}) greater than an offset voltage signal V_{off}. An offset voltage V_{off} is the threshold that must be overcome before any useful signals are generated. More specifically, the magnetic field (H) generated by the magnetization (M) of the magnetic switch must be strong enough at point P to generate an induced voltage in sensor 130 greater than V_{off} before the stored data can be accurately detected. Thus, the current (I) must be sufficiently large enough to create a strong enough magnetization (M) in the magnetic component 122. In the alternative, each memory cell 10 may be subjected to a bias magnetic field as described in copending U.S. patent application Ser. No. 11/189,822, which is incorporated herein by reference in its entirety, to compensate for the offset voltage effect V_{off}.

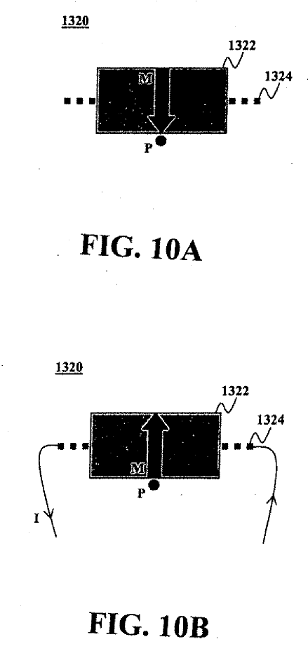

For purposes of illustration only, FIGS. 10A and 10B show at a partial side view of an exemplary embodiment of a magnetic component 1322 of a memory cell 1310 of a magnetic memory device according to the present invention. Referring to FIG. 10A, the magnetic component 1322 has an initial direction of magnetization (M) oriented downward. FIG. 10B shows that after a sufficiently high current (I) is sent through the coil 1324, the magnetic component 1322 retains an induced magnetization whose direction is oriented upward. In this case, the magnetic induction proximate to the surface of the magnetic component 1322, at detection point P, is the field generated by the magnetic component 1322. This field causes the sensor 130 to generate a voltage signal that should have a magnitude greater than the voltage signal V_{off} and a sign indicating the direction of magnetization (e.g., a positive voltage for “upward”). If an upward magnetization is designated as “1,” then the sensor 130 detects the stored data as being “1.”

To then attain a downward magnetization (i.e., “0”), a suitable current (e.g., current pulse in the opposite direction) is again sent through the coil 1324 to generate a magnetic field −H_{wire} (i.e., with the opposite orientation than H_{wire}) sufficient to change (i.e., flip) the magnetization of the magnetic component 1322. After the pulse, the magnetic component 1322 retains a magnetization that may have smaller magnitude or whose direction is oriented downward. In this case, the magnetic field at detection point P is the magnetic field generated by the magnetic component 1322. The detected induction at point P causes the sensor 130 to generate a voltage signal that has a smaller magnitude or opposite sign indicating the direction of magnetization (e.g., a negative voltage for “downward”). If a downward or smaller magnetization is designated as “0,” then the sensor 130 detects the stored data as being “0.” While FIGS. 10A and 10B are shown using a coil 1324 to set a magnetization level and direction in the magnetic component 1322, other configurations may be used, such as the write line of 924 of FIG. 8, may be used without departing from the scope of the invention.

The magnetic memory device according to the present invention was described in relation to a magnetic switch over a Hall effect sensor. In particular, the advantages of a magnetic component that can retain a magnetic field without any power supplied thereto and a simple sensor for reading the stored magnetic field provides a non-volatile memory device that consumes very little power for operation compared to the electric-based memory devices currently in use. Moreover, the ability to grow high carrier mobility structure, such as GaAs on a silicon wafer in accordance with the present invention allows combining the magnetic memory structure of the present invention in existing semiconductor devices, such as CMOS devices.

The magnetic memory device according to the present invention has various applications including, but not limited to, radio frequency identification tags (RFIDs), personal digital assistants (PDAs), cellular phones, and other computing devices. For instance, the magnetic memory device according to the present invention has uses for aerospace/defense, sensors, and RFID applications. The magnetic random access memory of the present invention has been developed for low density radiation hard applications. The magnetic random access memory of the present invention is non-volatile, read/write addressable, and fabricated from radiation hard materials. The applicable and emerging markets include aerospace and defense, such as rad-hard military and radar systems, satellite, and security applications, sensors, and RFID. Sensors in automotive applications, medial equipment like bioelectronics, biosensors, and gas/liquid/energy metering, and seismic monitoring for oil and gas exploration, for example, are all envisioned as potential uses for the present invention. Future growth and technical evolution is anticipated in the pervasive computing, PDA, and display markets as well.

It will be apparent to those skilled in the art that various modifications and variations can be made in the magnetic switch of the present invention and fabrication process therefor without departing from the spirit or scope of the invention. Thus, it is intended that the present invention cover the modifications and variations of this invention provided they come within the scope of the appended claims and their equivalents.

What is claimed is:

1. A method for making a magnetic memory cell comprising a Hall effect sensor on a substrate comprising:
(i) preparing a substrate;
(ii) forming an amorphous layer on the substrate on the substrate;
(iii) heating the amorphous layer; and
(iv) epitaxially growing a material on the amorphous layer.

2. The method of claim 1, wherein the substrate is a silicon substrate.

3. The method of claim 1, wherein the amorphous layer is comprised of a group III-V material.

4. The method of claim 1, wherein the III-V material is a low temperature III-V material.

5. The method of claim 1, wherein the amorphous III-V material layer is GaAs.

6. The method of claim 1, wherein the epitaxially grown material is a 2DEG structure.

7. The method of claim 5, wherein the epitaxially grown material is a 2DEG structure constructed from AGaAs/GaAs.

8. The method of claim 1 further comprising using high electron mobility materials to form a Hall effect sensor on a silicon substrate, which will be used to detect the direction of magnetization of a magnetic storage element or bit.

9. A fabrication method for making a magnetic memory cell comprising a Hall effect sensor on a substrate comprising the steps of:
(i) preparing a silicon substrate;
(ii) forming an amorphous III-V material layer on the silicon substrate;
(iii) heating the amorphous III-V material layer; and
(iv) epitaxially growing. III-V material on the amorphous III-V material layer.

10. The method of claim 9, wherein the III-V material is a low temperature III-V material.

11. The method of claim 9, wherein the III-V material layer is GaAs.

12. The method of claim 9, wherein the epitaxially grown material is a 2DEG structure.

13. The method of claim 9, wherein the epitaxially grown material is a 2DEG structure constructed from AGaAs/GaAs.

14. The method of claim 9 further comprising the steps of:
(i) preparing a silicon substrate;
(ii) forming a silicon dioxide layer, and
(iii) epitaxially growing a SiGe layer on the silicon dioxide layer.

15. The method of claim 14, wherein the SiGe layer is the basis for a Hall effect sensor.

16. The method of claim 8, wherein the magnetic storage element is comprised of plated magnetic material, which can have its magnetization switched by applying a current to a coil proximate to the magnetic material.

17. The method of claim 8, wherein the magnetic material is a soft magnetic material.

18. The method of claim 17, wherein the soft magnetic material is 80:20 NiFe, 45:55 NiFe, or NiFeCo.

19. The method of claim 8, wherein the magnetic material is deposited onto the substrate to form a horseshoe-shaped magnet.

20. The method of claim 1, wherein the magnetic storage element is comprised of a sputter deposited or evaporated magnetic material, which can have its magnetization switched by applying a current to a coil proximate to the magnetic material.

21. The method of claim 11, wherein the magnetic material is a soft magnetic material.

22. The method of claim 8, wherein the soft magnetic material is 80:20 NiFe, 45:55 NiFe, or NiFeCo.

23. The method of claim 1, wherein the starting substrate is an SOI-type substrate with the device side of the SOI comprised of a high electron mobility material.

24. The method of claim 14, wherein the starting substrate is comprised of a SiGe SOI substrate.

25. A method for making a magnetic memory cell comprising a Hall effect sensor on a substrate comprising:
(i) preparing a silicon substrate;
(ii) forming a compliant buffer layer on the silicon substrate;
(iii) heating the compliant buffer layer; and
(iv) epitaxially growing a group III-V material on the compliant buffer layer.

26. The method of claim 23, wherein the group III-V material is GaAs.

27. The method of claim 23, wherein the epitaxially grown material is a 2DEG structure.

28. The method of claim 25, wherein the epitaxially grown material is a 2DEG structure constructed from AGaAs/GaAs.
